(19) United States
(12) Patent Application Publication
(10) Pub. No.: US 2026/0314265 A1
(43) Pub. Date: Oct. 8, 2026

(54) ULTRASONIC-WAVE IRRADIATION UNIT

(71) Applicant: HONDA ELECTRONICS CO., LTD., Aichi (JP)

(72) Inventors: Atsuhiro HAYASHI, Aichi (JP); Nobunaga SHIBUYA, Aichi (JP); Kenji NAGAREDA, Aichi (JP)

(73) Assignee: HONDA ELECTRONICS CO., LTD., Aichi (JP)

(21) Appl. No.: 19/542,955

(22) Filed: Feb. 18, 2026

(30) Foreign Application Priority Data
Apr. 3, 2025 (JP) 2025-062087

(51) Int. Cl. H10N 30/88; B06B 1/06; B08B 3/12; H10N 30/853

(52) U.S. Cl. CPC H10N 30/88; B06B 1/0622; B08B 3/12; H10N 30/853

(57) ABSTRACT

To provide a low-cost ultrasonic radiation unit that offers long service life through excellent erosion resistance and achieves uniform ultrasonic cleaning owing to improved uniformity of oscillation-displacement distribution. The unit includes a diaphragm, multiple bolt-clamped Langevin-type ultrasonic transducers, and resonant rods that resonate at the same frequency and in the same longitudinal mode as the transducers. The transducers, each using four or more lead-free piezoelectric ceramic elements, are arranged at the vertices of a regular hexagon assumed at a central portion of the diaphragm. A first resonant rod with a relatively large cross-section is disposed at the center of the assumed hexagon and at positions adjacent to its outside along a short side of the diaphragm. A second resonant rod with a relatively small cross-section is disposed at positions adjacent to the outside of the assumed hexagon along a long side of the diaphragm.

### TECHNICAL FIELD

The present invention relates to an ultrasonic-wave irradiation unit that irradiates ultrasonic waves from an ultrasonic transducer.

### BACKGROUND ART

Conventionally, ultrasonic cleaning apparatuses equipped with an ultrasonic-wave irradiation unit, which perform cleaning of an object to be cleaned (ultrasonic cleaning) by irradiating the cleaning liquid with ultrasonic waves, have been widely used. Ultrasonic cleaning combines the physical action of ultrasonic waves with the chemical action of the cleaning liquid, allowing it to act even on the fine details of objects having complex shapes, thereby enabling efficient cleaning. Consequently, ultrasonic cleaning has become indispensable in the manufacturing of precision mechanical parts, optical components, liquid crystal displays (LCDs), semiconductors, and the like.

A conventional ultrasonic cleaning device 200 shown in FIG. 8 is equipped with a diaphragm 201, which is also called a radiating plate. The diaphragm 201 often serves as a bottom of a cleaning tank 202 and is formed of a stainless-steel plate having a thickness of several millimeters. On a non-irradiation surface 203 of the diaphragm 201, which constitutes an ultrasonic-wave irradiation unit, a plurality of bolt-clamped Langevin-type ultrasonic transducers 204 are bonded. One surface of the diaphragm 201 located on the opposite side of the non-irradiation surface 203 serves as an ultrasonic irradiation surface 205. When an ultrasonic-wave irradiation unit that generates ultrasonic waves of several tens of kilohertz is used, strong shock waves resulting from cavitation produced in the cleaning liquid 206 by the ultrasonic waves clean an object 207 to be cleaned.

### Prior Art Documents

### Patent Document

Patent Document 1 JP 2019-058883 A (see FIG. 1 and others)

### SUMMARY OF THE INVENTION

### Problems to be Solved by the Invention

When the cleaning area of the ultrasonic cleaning device 200 becomes large, the radiation surface of the diaphragm 201 also increases accordingly. Therefore, in constructing an ultrasonic-wave irradiation unit, it is generally preferable to install a larger number of ultrasonic transducers 204 on a diaphragm 201 having a large radiation surface. However, using many ultrasonic transducers 204 increases the manufacturing cost of the device. Conversely, if an insufficient number of ultrasonic transducers 204 are installed relative to the size of the diaphragm 201, inactive regions (areas not equipped with transducers) are formed between adjacent transducers. As a result, erosion 208 may occur on the diaphragm 201 due to cavitation. In addition, nonuniformity in the oscillation-displacement distribution, resulting in variations in the sound pressure distribution, leads to uneven cleaning performance.

Accordingly, the inventors of the present application have already proposed an ultrasonic-wave irradiation unit having a structure in which resonant rods are arranged between a plurality of ultrasonic transducers (see, for example, Patent Document 1). With this configuration, it is possible to reduce areas on the non-irradiation surface where neither transducers nor resonant rods are present. However, even with this configuration, sufficient reduction of erosion and sufficient uniformity of the oscillation-displacement distribution have not yet been achieved.

The present invention has been made in view of the above issues. An object of the invention is to provide an ultrasonic-wave irradiation unit that offers a long service life due to excellent erosion resistance, ensures high uniformity of oscillation-displacement distribution to minimize cleaning unevenness, and can be manufactured at low cost.

### Means for Solving the Problems

The first aspect of the present invention refers to an ultrasonic-wave irradiation unit comprising: a diaphragm having an irradiation surface for irradiating ultrasonic waves and a non-irradiation surface located on the opposite side of the irradiation surface, the non-irradiation surface being provided with protruding bolts and the diaphragm having a rectangular planar shape; a plurality of bolt-clamped Langevin-type ultrasonic transducers, each having a transducer front plate joined to the non-irradiation surface; and a plurality of resonant rods that resonate at the same frequency and in the same longitudinal oscillation mode as the ultrasonic transducers, wherein the plurality of ultrasonic transducers and the plurality of resonant rods are fastened and fixed to the diaphragm via the plurality of bolts,wherein each of the plurality of ultrasonic transducers is configured using four or more piezoelectric elements made of lead-free piezoelectric ceramics and is disposed at each vertex of at least one assumed regular hexagon assumed at a central portion of the diaphragm, and wherein the plurality of resonant rods include first resonant rods having a relatively larger cross-sectional area and second resonant rods having a relatively smaller cross-sectional area, the first resonant rods being disposed at a central position of the regular hexagon and at positions on the short-side portions of the diaphragm that are located adjacent to the outside of the regular hexagon, and the second resonant rods being disposed on the long-side portions of the diaphragm at positions located adjacent to the outside of the regular hexagon.

Accordingly, according to the first aspect of the present invention, since each ultrasonic transducer is configured using four or more piezoelectric elements made of lead-free piezoelectric ceramics, a larger driving power can be supplied to each transducer as compared with a transducer that uses only two piezoelectric elements. In addition, by arranging the ultrasonic transducers at the vertices of at least one regular hexagon assumed at a central portion of the diaphragm having a rectangular planar shape, the diaphragm can be efficiently excited with a relatively small number of transducers. Furthermore, by arranging first resonant rods and second resonant rods having different cross-sectional areas in predetermined respective arrangements, uniform longitudinal oscillation can be obtained over a relatively wide irradiation surface of the diaphragm. As a result, the occurrence of erosion on the diaphragm is reduced, and a more uniform oscillation displacement distribution can be achieved.

Moreover, since each resonant rod has a simpler structure than the ultrasonic transducer, which is composed of various components, it can be manufactured at a relatively low cost. Therefore, even in an ultrasonic-wave irradiation unit used in applications requiring a large cleaning area, it is possible to realize an ultrasonic-wave irradiation unit that exhibits excellent erosion resistance and uniformity of oscillation displacement distribution at low cost by reducing the number of ultrasonic transducers used and employing inexpensive resonant rods.

The second aspect of the present invention refers to the ultrasonic-wave irradiation unit according to the first aspect, wherein two assumed regular hexagons that share one side with each other are assumed at a central portion of the diaphragm, and the plurality of ultrasonic transducers are disposed at the vertices of the two regular hexagons.

The third aspect of the present invention refers to the ultrasonic-wave irradiation unit according to the first aspect, wherein the number of the ultrasonic transducers is smaller than the total number of the first resonant rods and the second resonant rods, and the number of the first resonant rods is greater than that of the second resonant rods.

The fourth aspect of the present invention refers to the ultrasonic-wave irradiation unit according to the first aspect, wherein the first resonant rods are linearly arranged along the short side of the diaphragm and are provided in a number of three or more.

The fifth aspect of the present invention refers to the ultrasonic-wave irradiation unit according to the first aspect, wherein the first resonant rod has a diameter (D1) equal to the maximum diameter (D0) of the front plate of the ultrasonic transducer, and the second resonant rod has a diameter (D2) that is not less than one-half and not greater than three-fourths of the maximum diameter (D0) of the front plate of the ultrasonic transducer.

The sixth aspect of the present invention refers to the ultrasonic-wave irradiation unit according to the first aspect, wherein a center-to-center distance (L1) between each first resonant rod and the ultrasonic transducer adjacent thereto is equal to a center-to-center distance (L0) between two adjacent ultrasonic transducers, and a center-to-center distance (L2) between each second resonant rod and the ultrasonic transducer adjacent thereto is shorter than the center-to-center distance (L0) between the two adjacent ultrasonic transducers.

### Effects of the Invention

As described above, according to the inventions of the first to sixth aspects, an ultrasonic-wave irradiation unit having excellent erosion resistance and a long service life, and capable of being realized at low cost while achieving a highly uniform oscillation-displacement distribution, thereby reducing unevenness in cleaning.

### BRIEF DESCRIPTION OF THE DRAWINGS

FIG. 1 is a schematic configuration diagram illustrating an ultrasonic cleaning device according to an embodiment.

FIG. 2 is a plan view illustrating a diaphragm-type ultrasonic-wave irradiation unit according to the embodiment.

FIG. 3 is a cross-sectional view taken along line A–A in FIG. 2.

FIG. 4 is a cross-sectional view taken along line B–B in FIG. 2.

FIG. 5 is a table illustrating analysis results of oscillation displacement for Comparative Example 1, Comparative Example 2, and the Example.

FIG. 6 is a plan view illustrating another embodiment of the diaphragm-type ultrasonic-wave irradiation unit.

FIG. 7 is a plan view illustrating yet another embodiment of the diaphragm-type ultrasonic-wave irradiation unit.

FIG. 8 is a schematic configuration diagram illustrating a conventional ultrasonic cleaning device.

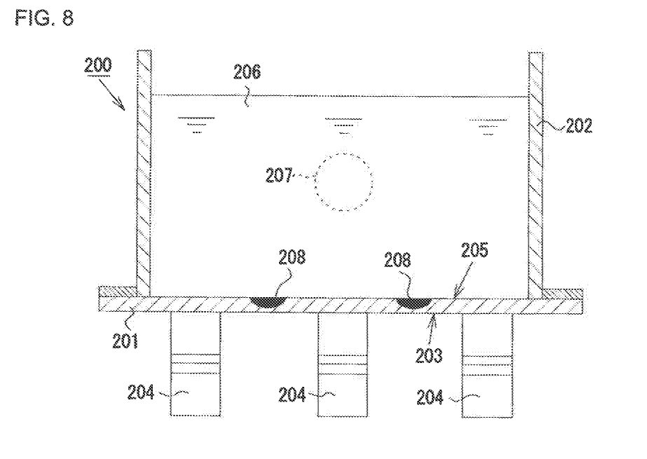

### MODE FOR CARRYING OUT THE INVENTION

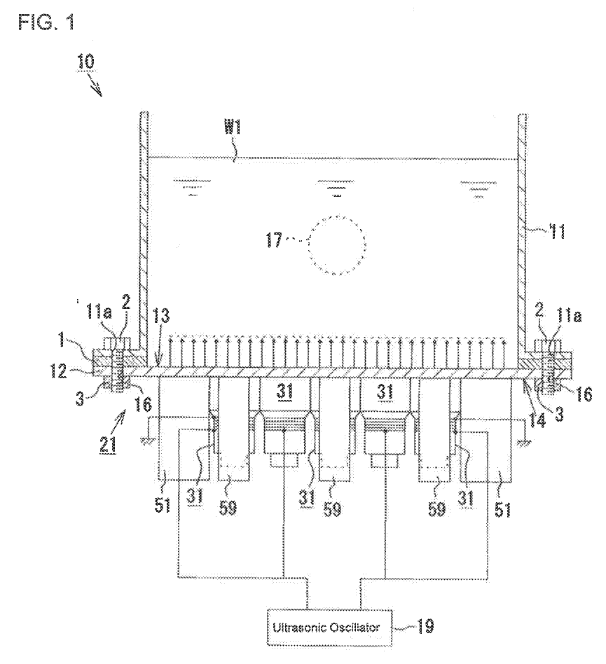

Hereinafter, an embodiment in which the present invention is embodied in an ultrasonic cleaning device will be described in detail with reference to FIGS. 1 to 5.

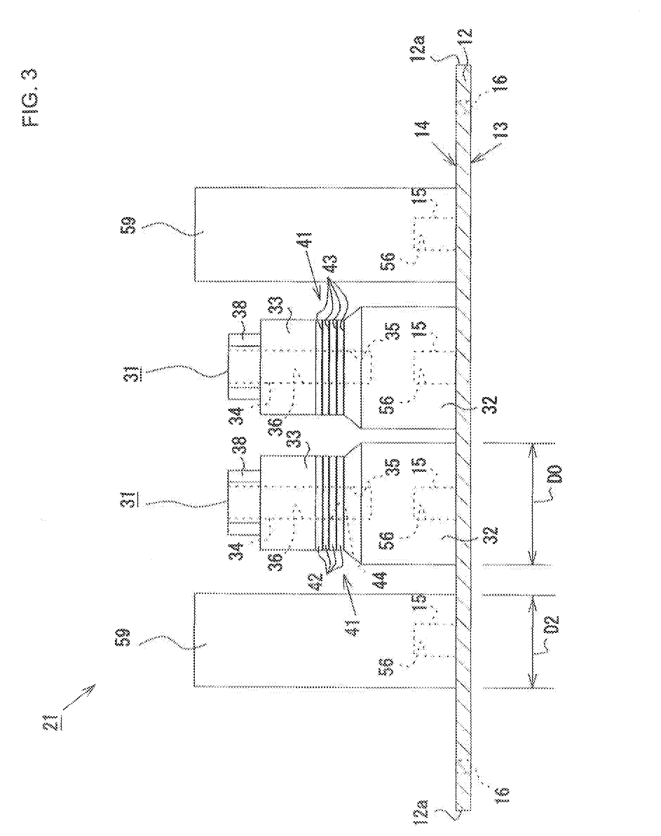

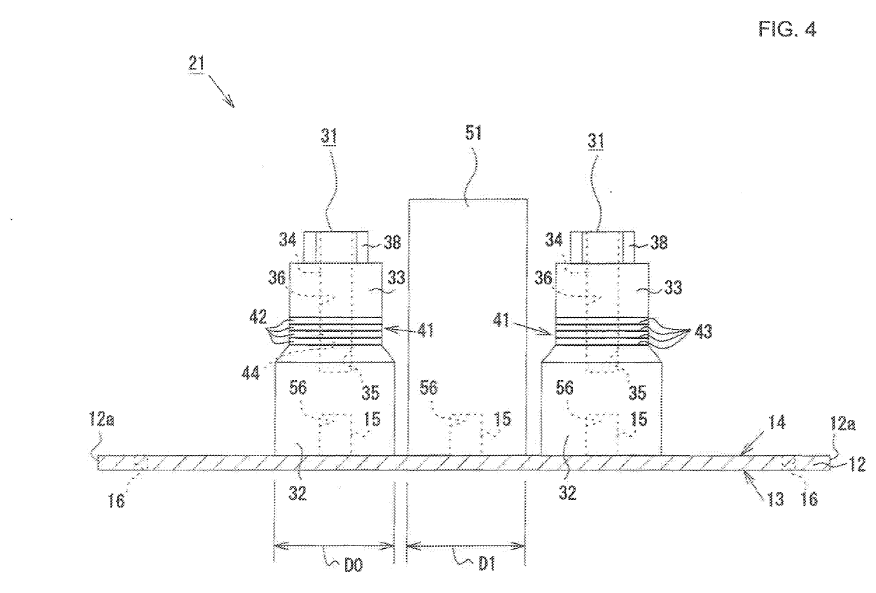

As shown in FIG. 1, an ultrasonic cleaning device 10 includes a metallic cleaning tank 11 for storing a cleaning liquid W1 and an ultrasonic-wave irradiation unit 21. A plurality of bolt holes 11a are formed in a lower end portion of the cleaning tank 11. A diaphragm 12 of the ultrasonic-wave irradiation unit 21 constitutes the bottom portion of the cleaning tank 11 and is a rectangular metal plate in plan view (in this embodiment, a stainless-steel plate) having a vertical dimension of 390 mm, a horizontal dimension of 240 mm, and a thickness of 2.5 mm. That is, the ultrasonic-wave irradiation unit 21 of this embodiment is a diaphragm-type ultrasonic-wave irradiation unit in which the diaphragm 12 is disposed at the lower end portion of the cleaning tank 11 via a packing 1, and the diaphragm 12 is fastened by bolts 2 and nuts 3. The diaphragm 12 has an irradiation surface 13 that irradiates ultrasonic waves and a non-irradiation surface 14 located on the opposite side of the irradiation surface 13. A plurality of stud bolts 15 (see FIGS. 3 and 4) project from multiple positions on the non-irradiation surface 14 of the diaphragm 12. A plurality of fixing holes 16 are provided at substantially equal intervals along the entire circumference of an outer peripheral portion of the diaphragm 12.

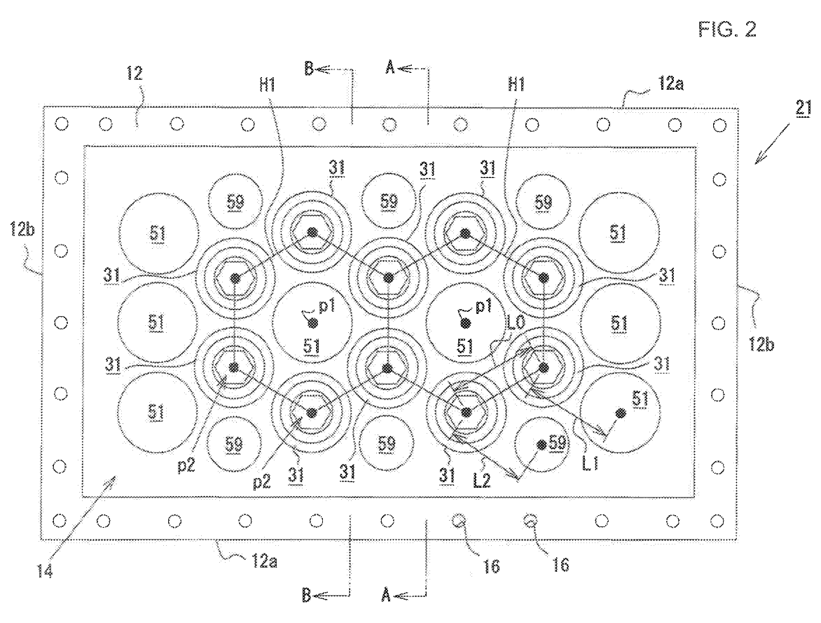

As shown in FIGS. 1 and 2, the ultrasonic-wave irradiation unit 21 includes the diaphragm 12 described above, a plurality of bolt-clamped Langevin-type ultrasonic transducers 31, and a plurality of resonant rods 51 and 59. The ultrasonic cleaning device 10 of this embodiment, which employs the ultrasonic-wave irradiation unit 21, is configured to clean a surface of a workpiece 17 (see FIG. 1) accommodated in the cleaning tank 11 by irradiating ultrasonic waves from each of the ultrasonic transducers 31 into the cleaning liquid W1 in the cleaning tank 11.

As shown in FIGS. 3 and 4, each ultrasonic transducer 31 is a device for irradiating ultrasonic waves and includes a transducer front plate 32, a transducer backing plate 33, a driving section 41, and bolts 34 and nuts 38 for assembling the transducer. That is, each ultrasonic transducer 31 of this embodiment is a bolt-clamped Langevin-type transducer (BLT). The transducer front plate 32 is disposed at the front end side of the ultrasonic transducer 31. The transducer front plate 32 is circular in plan view and substantially cylindrical in shape. A circular irradiation surface of the transducer front plate 32 is joined to a non-irradiation surface 14 of the diaphragm 12 via an adhesive such as an epoxy resin adhesive. The transducer front plate 32 is formed of a metallic material such as aluminum, aluminum alloy, stainless steel, or titanium alloy.

A transducer backing plate 33 is disposed at the rear end side of the ultrasonic transducer 31. The transducer backing plate 33 is circular in plan view and substantially cylindrical in shape, and in this embodiment, the backing plate 33 is configured to have a slightly smaller diameter than that of the transducer front plate 32. A driving section 41 is formed by alternately stacking four piezoelectric elements 42 and four electrode plates 43, and is clamped between the transducer front plate 32 and the transducer backing plate 33. The transducer backing plate 33 is formed of a metallic material such as aluminum, aluminum alloy, stainless steel, or titanium alloy.

Each piezoelectric element 42 has an annular shape, and each electrode plate 43 has a substantially annular shape with a tab portion formed on a part thereof. Accordingly, the driving section 41 is formed with a bolt insertion hole 44 that penetrates through its center. Each piezoelectric element 42 is polarized in the thickness direction.

The piezoelectric elements 42 of this embodiment are formed using a lead-free piezoelectric ceramic material. Although the lead-free piezoelectric ceramics are not particularly limited, preferred examples include, for instance, alkali niobate–based piezoelectric ceramic materials and BNT–BT–based piezoelectric ceramic materials mainly composed of bismuth sodium titanate and barium titanate.

As shown in FIGS. 3 and 4, a female-threaded hole 35 that extends along the height direction of the transducer front plate 32 (i.e., the vertical direction in FIGS. 3 and 4) is formed at a central portion on a rear-end side of the transducer front plate 32. The female-threaded hole 35 does not penetrate through the transducer front plate 32; in other words, it opens only on the rear surface of the transducer front plate 32. On the other hand, a bolt insertion hole 56 that extends along the height direction and through which a stud bolt 15 is inserted is provided at a central portion on a front-end side of the transducer front plate 32.

The female-threaded hole 35 of the transducer front plate 32 communicates with the bolt insertion hole 44 of the driving section 41. Meanwhile, a through hole 36 that extends along the height direction (i.e., the vertical direction in FIGS. 3 and 4) is formed at a central portion of the transducer backing plate 33. The through hole 36 opens at the front surface to communicate with the bolt insertion hole 44, and also opens at the rear surface.

A transducer assembly bolt 34, which has a male-threaded outer surface, is inserted from the side of the transducer backing plate 33, and its distal end extends through the through hole 36 and the bolt insertion hole 44 to reach the female-threaded hole 35 of the transducer front plate 32. In other words, the distal end of the transducer assembly bolt 34 stops midway within the transducer front plate 32 and does not reach the diaphragm 12. The transducer assembly bolt 34 is threadably engaged with the female-threaded hole 35. By fastening a nut 38 onto a projecting portion of the transducer assembly bolt 34 that passes through the transducer backing plate 33, the transducer front plate 32, the driving section 41, and the transducer backing plate 33 are tightened and integrally fixed together. Although the metallic materials forming the transducer assembly bolt 34 and the nut 38 are not particularly limited, stainless steel is used in this embodiment.

A plurality of stud bolts 15 projecting from the non-irradiation surface 14 of the diaphragm 12 are threadably engaged with the bolt insertion holes 56 of the transducer front plates 32. By this threaded engagement, the plurality of ultrasonic transducers 31 are fastened and fixed to the diaphragm 12.

Each ultrasonic transducer 31 of this embodiment, as shown in FIG. 1 and other figures, is a longitudinal-vibration-type bolt-clamped Langevin-type transducer having an axial longitudinal oscillation component that resonates at a λ/2 wavelength (λ: wavelength of longitudinal oscillation) in a fundamental longitudinal oscillation mode, with a standalone resonance frequency of 28 kHz. All of the ultrasonic transducers 31 oscillate at the same frequency.

As shown in FIG. 1, each ultrasonic transducer 31 is electrically connected to an ultrasonic oscillator 19. The ultrasonic oscillator 19 supplies high-frequency electric power that continuously drives each ultrasonic transducer 31 to oscillate. By this high-frequency electric power, each ultrasonic transducer 31 is driven, and ultrasonic waves having a frequency of 25 kHz (which is the mounted resonance frequency of each ultrasonic transducer 31 when bonded to the diaphragm 12) are irradiated into the cleaning liquid W1 within the cleaning tank 11. In this embodiment, the output (driving power) of the ultrasonic waves is set to 600 W; however, the output is not particularly limited to this value and may be set arbitrarily.

As shown in FIGS. 1 to 4, the plurality of resonant rods in this embodiment are composed of first resonant rods 51 having a relatively large cross-sectional area and second resonant rods 59 having a relatively small cross-sectional area.

The first resonant rod 51 is a resonator that resonates at the same frequency (a standalone resonance frequency of 28 kHz) and in the same longitudinal oscillation mode as the ultrasonic transducer 31. The first resonant rod 51 is circular in plan view and substantially cylindrical in shape. In this embodiment, the first resonant rod 51 has a diameter D1 equal to the maximum diameter D0 of the transducer front plate 32 and is formed slightly longer than the ultrasonic transducer 31 (see FIG. 4). Specifically, since the maximum diameter D0 of the transducer front plate 32 is 45 mm in diameter (φ45 mm), the diameter D1 of the first resonant rod 51 is also 45 mm in diameter (φ45 mm). A bolt insertion hole 56, through which the stud bolt 15 is inserted, is formed at a central portion on the front end side of the first resonant rod 51 so as to extend along the height direction. By threadably engaging the stud bolt 15 with the bolt insertion hole 56 of the first resonant rod 51, the first resonant rod 51 is fastened and fixed to the diaphragm 12.

The second resonant rod 59, like the first resonant rod 51, is a resonator that resonates at the same frequency (its standalone resonance frequency of 28 kHz) and in the same longitudinal oscillation mode as the ultrasonic transducer 31. The second resonant rod 59 is circular in plan view and substantially cylindrical in shape. In this embodiment, the second resonant rod 59 has a diameter D2 that is not less than one-half and not greater than three-fourths of the maximum diameter D0 of the transducer front plate 32 (see FIG. 3). If the diameter D2 is too large, it becomes difficult to position the second resonant rod 59 close to the ultrasonic transducer 31, and the distance from the long side 12a of the diaphragm 12 may not be sufficiently secured. Conversely, if the diameter D2 is too small, the advantageous effect obtained by providing the second resonant rod 59 may not be sufficiently achieved. Specifically, since the maximum diameter D0 of the transducer front plate 32 is 45 mm in diameter (φ45 mm), the diameter D2 of the second resonant rod 59 is 30 mm in diameter (φ30 mm), which corresponds to two-thirds of that value. The second resonant rod 59 is also formed slightly longer than the ultrasonic transducer 31. A bolt insertion hole 56 that extends along the height direction is formed at a central portion on the front end side of the second resonant rod 59, through which the stud bolt 15 is inserted. By threadably engaging the stud bolt 15 with the bolt insertion hole 56 of the second resonant rod 59, the second resonant rod 59 is fastened and fixed to the diaphragm 12.

The first resonant rods 51 and the second resonant rods 59 are formed of metallic materials such as aluminum, aluminum alloy, stainless steel, or titanium alloy. In this embodiment, the first resonant rods 51 and the second resonant rods 59 are formed of the same kind of metallic material, specifically stainless steel; however, different metallic materials may instead be used.

Next, the numbers and layout of the ultrasonic transducers 31, the first resonant rods 51, and the second resonant rods 59 in the ultrasonic-wave irradiation unit 21 will be described in detail. In the case of the ultrasonic-wave irradiation unit 21, a plurality of ultrasonic transducers 31 are arranged at vertex points p2 of at least one assumed regular hexagon H1 that is assumed at the central portion of the diaphragm 12 (see FIG. 2). More specifically, in this embodiment, two regular hexagons H1 that share one side with each other are assumed at the central portion of the diaphragm 12, and the plurality of ultrasonic transducers 31 are arranged at the vertex points p2 of the two assumed regular hexagons H1. Accordingly, as shown in FIG. 2, since ten vertex points p2 exist within a single diaphragm 12, the ultrasonic-wave irradiation unit 21 includes ten ultrasonic transducers 31.

The first resonant rods 51 are arranged at their respective centers p1 of the regular hexagons H1, and in this embodiment, there are two such first resonant rods 51. In addition, the first resonant rods 51 are also arranged at positions located on the short-side portions 12b of the diaphragm 12 and adjacent to the regular hexagons H1 from the outside. Specifically, the first resonant rods 51 are linearly arranged along the short sides 12b of the diaphragm 12, with three or more rods disposed in a row. In this embodiment, there are six such first resonant rods 51 arranged in this manner. Accordingly, the ultrasonic-wave irradiation unit 21 includes a total of eight first resonant rods 51.

The second resonant rods 59 are arranged at positions located on the long-side portions 12a of the diaphragm 12 and adjacent to the regular hexagons H1 from the outside. In this embodiment, there are six such second resonant rods 59. That is, in the present embodiment, the number of ultrasonic transducers 31 is ten, which is smaller than the total number of the first and second resonant rods 51 and 59 (8 + 6 = 14). In addition, the number of the first resonant rods 51 is eight, which is greater than the number of the second resonant rods 59 (six).

Furthermore, as shown in FIG. 2, the center-to-center distance L1 between the first resonant rod 51 and the adjacent ultrasonic transducer 31 is equal to the center-to-center distance L0 between two adjacent ultrasonic transducers 31. In addition, the center-to-center distance L2 between the second resonant rod 59 and the adjacent ultrasonic transducer 31 is slightly smallerthan the center-to-center distance L0 between the two adjacent ultrasonic transducers 31. The above center-to-center distances L0 and L1 are set to be approximately 1.1 to 1.5 times the maximum diameter D0 of the transducer front plate 32, while the center-to-center distance L2 is set to be approximately 0.8 to 0.95 times the center-to-center distances L0 and L1.

When operating the ultrasonic cleaning apparatus 10 configured as described above, the ultrasonic cleaning apparatus 10 is first driven so that high-frequency electric power is supplied from the ultrasonic oscillator 19 to the plurality of ultrasonic transducers 31, thereby causing each ultrasonic transducer 31 to oscillate continuously. As a result, ultrasonic waves are irradiated from the ultrasonic transducers 31 into the cleaning liquid W1. At this time, cavitation is generated in the cleaning liquid W1 due to the irradiation of ultrasonic waves, and the collapse of the cavitation bubbles produces impact forces that clean the surface of the object to be cleaned 17.

Next, the evaluation test of the ultrasonic-wave irradiation unit 21 and its results will be described.

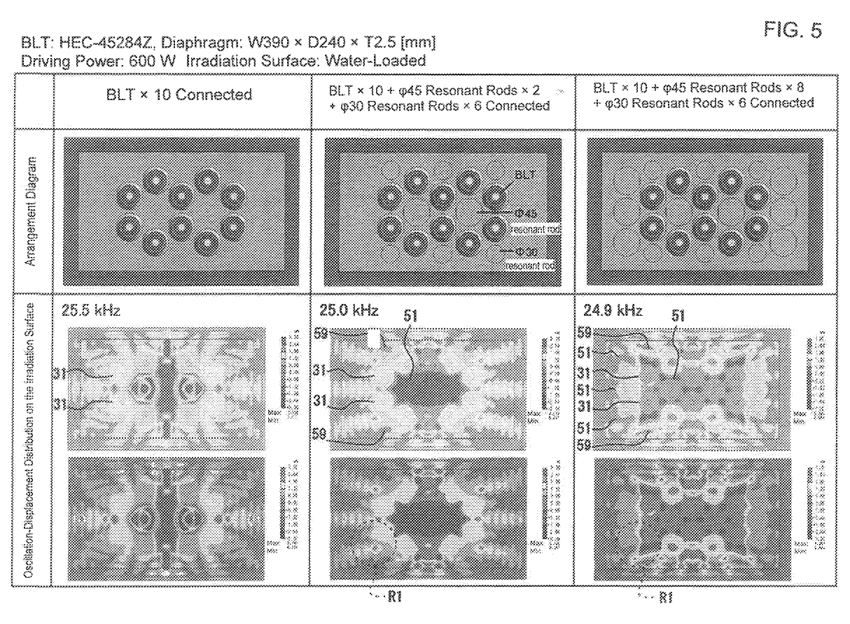

In this evaluation test, measurement samples were prepared as follows. An ultrasonic-wave irradiation unit 21 identical to that of the present embodiment was prepared and used as Example. The ultrasonic-wave irradiation unit 21 of the Example is shown in the right column of the table in FIG. 5 as “10 BLTs + φ45 resonant rods (8) + φ30 resonant rods (6) connected.” Further, an ultrasonic-wave irradiation unit in which six of the first resonant rods 51 were omitted from the ultrasonic-wave irradiation unit 21 of the present embodiment was prepared and used as Comparative Example 2. The ultrasonic-wave irradiation unit 21 of Comparative Example 2 is shown in the middle column of the table in FIG. 5 as “10 BLTs + φ45 resonant rods (2) + φ30 resonant rods (6) connected.” In addition, an ultrasonic-wave irradiation unit in which all of the first and second resonant rods 51 and 59 were omitted from the ultrasonic- wave irradiation unit 21 of the present embodiment was prepared and used as Comparative Example 1. The ultrasonic-wave irradiation unit 21 of Comparative Example 1 is shown in the left column of the table in FIG. 5 as “10 BLTs connected.”

Next, using a conventionally known finite element method (FEM) analysis, the oscillation-displacement distribution of the diaphragm 12 of the ultrasonic-wave irradiation unit of each measurement sample (the Example, Comparative Example 1, and Comparative Example 2) was analyzed under a water-loading condition. In this analysis, a diaphragm 12 having dimensions of 390 mm in length, 240 mm in width, and 2.5 mm in thickness was used. Ten ultrasonic transducers 31, each having a nominal frequency of 28 kHz (model “HEC-45282Z,” manufactured by Honda Electronics Co., Ltd.), were mounted on the non-irradiation surface 14 of the diaphragm 12 to form the ultrasonic-wave irradiation unit. The driving power of each ultrasonic transducer 31 was set to 600 W. The results of the analysis are shown in FIG. 5.

In Comparative Example 1, in which neither the first resonant rods 51 nor the second resonant rods 59 were used, it was confirmed that the oscillation displacement exhibited a significantly large value in a substantially cruciform region at the central portion of the diaphragm 12, while the oscillation displacement became small in the other regions. That is, it was found that the oscillation-displacement distribution in Comparative Example 1 exhibited a considerable degree of unevenness. In particular, marked unevenness in the oscillation-displacement distribution was observed in the vicinity of the center p1 of the regular hexagon H1, and erosion was likely to occur in that portion.

In contrast, in Comparative Example 2 - in which multiple second resonant rods 59 were added to Comparative Example 1 and a first resonant rod 51 was additionally placed at the center p1 of the regular hexagon H1 - it was confirmed that the substantially cross-shaped region exhibiting large oscillation displacement became slightly wider, and the unevenness in the oscillation-displacement distribution became somewhat smaller than that in Comparative Example 1. Such improvement is considered to result from the addition of the multiple second resonant rods 59. However, in Comparative Example 2, the oscillation displacement at the peripheral region of the diaphragm 12 did not become significantly large.

Furthermore, in the Example—where multiple first resonant rods 51 were additionally provided at positions adjacent to the outside of the regular hexagon H1—it was confirmed that the region exhibiting large oscillation displacement expanded further toward its surrounding area. Specifically, in Comparative Example 2, even though the ultrasonic transducers 31 and the second resonant rods 59 were present within the region indicated by the circle R1, the oscillation displacement in that region did not become significantly large. In contrast, in the Example, the oscillation displacement within the region indicated by the circle R1 became sufficiently large, and it was found that the unevenness in the oscillation-displacement distribution was considerably smaller than that in Comparative Example 2. Such improvement was considered to result from the addition of the multiple first resonant rods 51 at said outer adjacent positions. That is, in the Example, it was considered that the addition of the multiple first resonant rods 51 improved the diagonal-direction oscillation efficiency of the diaphragm 12, thereby contributing to the expansion of the region exhibiting large oscillation displacement and to the uniformity of the oscillation-displacement distribution.

Therefore, according to the present embodiment, the following advantageous effects can be achieved.

### The advantageous effects are as follows

(1) In the ultrasonic-wave irradiation unit 21 of the present embodiment, each ultrasonic transducer 31 is configured using four or more piezoelectric elements 42 made of a lead-free piezoelectric ceramic. Accordingly, compared with transducers that use only two piezoelectric elements 42, a larger driving power can be supplied to each individual transducer. In this ultrasonic-wave irradiation unit 21, the ultrasonic transducers 31, configured as described above, are arranged at the vertices p2 of two regular hexagons H1 assumed at the central portion of the diaphragm 12, which has a rectangular shape in plan view. Therefore, even with a relatively small number of ultrasonic transducers 31, the diaphragm 12 can be oscillated efficiently. Furthermore, by arranging the first resonant rods 51 and the second resonant rods 59, which have different cross-sectional areas, in respective predetermined configurations, uniform longitudinal oscillation can be obtained over the relatively wide irradiation surface of the diaphragm 12. As a result, erosion on the diaphragm 12 is reduced, and the diaphragm 12 becomes less susceptible to wear, thereby enabling the service life of the apparatus to be extended. In addition, a uniform oscillation-displacement distribution can be more easily obtained, which reduces the occurrence of uneven cleaning. Consequently, an excellent ultrasonic cleaning apparatus 10 capable of achieving uniform cleaning can be provided.

In addition, the first resonant rods 51 and the second resonant rods 59 of the present embodiment, which are each formed of a single material, have a simpler structure than the ultrasonic transducers 31, which are composed of multiple components. Accordingly, they can be manufactured at relatively low cost. Therefore, even in an ultrasonic-wave irradiation unit 21 equipped with a diaphragm 12 that requires a wide cleaning area, it is possible to reduce the number of ultrasonic transducers 31 used and to use the inexpensive resonant rods 51 and 59. As a result, a low-cost apparatus having excellent erosion resistance and superior uniformity in oscillation-displacement distribution can be achieved.

(2) In the ultrasonic-wave irradiation unit 21 of the present embodiment, two first resonant rods 51 are arranged at their respective central positions p1 of the regular hexagon H1, and six first resonant rods 51 are arranged on the short side 12b of the diaphragm 12 at positions adjacent to the outside of the regular hexagon H1. As shown in FIG. 2, three first resonant rods 51 are arranged linearly on the right-hand short side 12b of the diaphragm 12, and likewise, three first resonant rods 51 are arranged linearly on the left-hand short side 12b. In addition, six second resonant rods 59 are arranged on the long side 12a of the diaphragm 12 at positions adjacent to the outside of the regular hexagon H1. Furthermore, the number of ultrasonic transducers 31 is smaller than the total number of the first and second resonant rods 51 and 59, and the number of the first resonant rods 51 is greater than the number of the second resonant rods 59. With the above configuration, the oscillation efficiency along the diagonal direction of the diaphragm 12 can be particularly improved. Accordingly, the region exhibiting large oscillation displacement can be expanded, and the uniformity of the oscillation-displacement distribution can be improved.

The above embodiment may be modified in various ways, including the following.

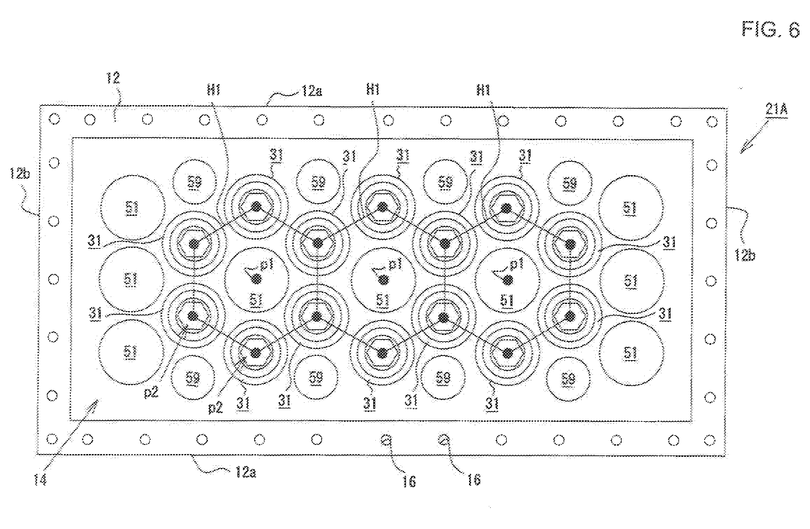

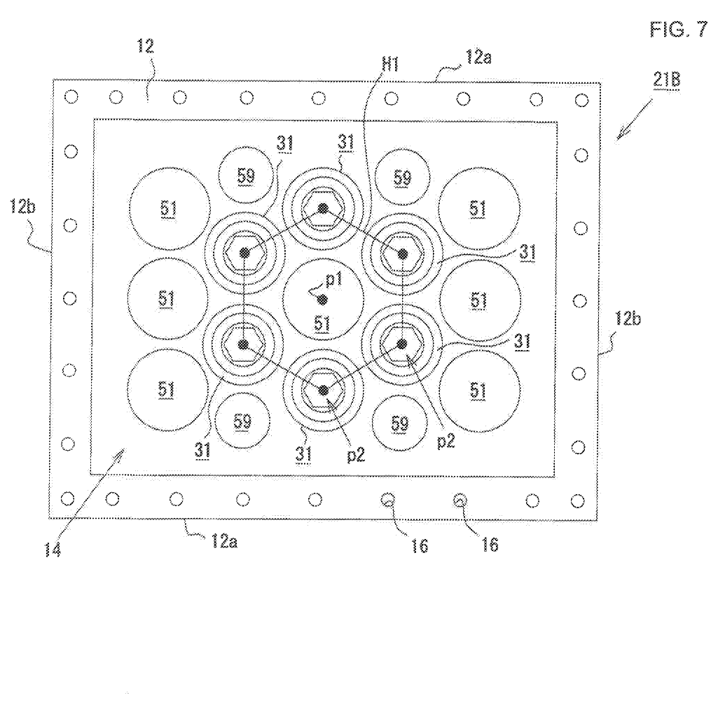

In the above embodiment, two regular hexagons H1 that share one side with each other are assumed at the central portion of the diaphragm 12, and multiple ultrasonic transducers 31 are arranged at the vertices p2 of the two regular hexagons H1 to constitute the ultrasonic-wave irradiation unit 21; however, the present invention is not limited thereto. For example, as in the ultrasonic-wave irradiation unit 21A of another embodiment shown in FIG. 6, three regular hexagons H1 that share at least one side with each other may be assumed at the central portion of the diaphragm 12, and multiple ultrasonic transducers 31 may be arranged at the vertices p2 of the three regular hexagons H1. In the ultrasonic-wave irradiation unit 21A, the unit is configured using fourteen ultrasonic transducers 31, nine first resonant rods 51, and eight second resonant rods 59. Alternatively, as in the ultrasonic-wave irradiation unit 21B of another embodiment shown in FIG. 7, one regular hexagon H1 may be assumed at the central portion of the diaphragm 12, and multiple ultrasonic transducers 31 may be arranged at the vertices p2 of the one regular hexagon H1. In the ultrasonic-wave irradiation unit 21B, the unit is configured using six ultrasonic transducers 31, seven first resonant rods 51, and four second resonant rods 59.

In the above embodiment, each of the multiple ultrasonic transducers 31 is configured using four piezoelectric elements 42 made of a lead-free piezoelectric ceramic; however, the invention is not limited thereto. For example, multiple ultrasonic transducers 31 may instead be configured using six or eight piezoelectric elements 42.

In the above embodiment, the ultrasonic-wave irradiation unit 21 is configured using the first resonant rods 51 and the second resonant rods 59, each of which is circular in plan view and substantially cylindrical in shape; however, the invention is not limited thereto. For example, the ultrasonic-wave irradiation unit 21 may instead be configured using the first resonant rods 51 and the second resonant rods 59 that are rectangular in plan view and substantially prismatic in shape. In this case, the shapes of the first resonant rods 51 and the second resonant rods 59 may be the same or different.

In the above embodiment, the diameter D1 of the first resonant rod 51 is equal to the maximum diameter D0 of the transducer front plate 32, and both are 45 mm (φ45); however, the invention is not limited thereto. For example, the diameter D1 of the first resonant rod 51 may be either larger or smaller than the maximum diameter D0 of the transducer front plate 32. Incidentally, when the diameter D1 of the first resonant rod 51 is set equal to the maximum diameter D0 of the transducer front plate 32, as in the above embodiment, it is advantageous for achieving greater uniformity in the oscillation-displacement distribution.

In the above embodiment, the stud bolts 15, which are headless bolts, are used as bolts that protrude from the non-irradiation surface 14 of the diaphragm 12. However, bolts having heads—such as hexagonal bolts, hexagon-socket head bolts, and wing bolts - may instead be used as the bolts that protrude from the non-irradiation surface 14.

In the above embodiment, the diaphragm-type ultrasonic-wave irradiation units 21, 21A, and 21B are mounted to the bottom portion of the cleaning tank 11 in the ultrasonic cleaning apparatus 10 with a packing 1 interposed therebetween. However, this is not limiting. For example, the ultrasonic-wave irradiation units 21, 21A, and 21B may be of a tank-mounted type that are attached to stud bolts protruding from the non-irradiation surface of the bottom plate of the cleaning tank 11. Alternatively, the ultrasonic-wave irradiation units 21, 21A, and 21B may be of an immersible type that are used by being placed in the cleaning liquid W1 in the cleaning tank 11.

In the above embodiment, the ultrasonic-wave irradiation units 21, 21A, and 21B are each applied to the ultrasonic cleaning apparatus 10 that performs cleaning using ultrasonic waves; however, this is not limiting. For example, the ultrasonic-wave irradiation units may be applied to devices that perform processes such as extraction, emulsification, dispersion, mixing, agitation, crushing, or atomization, in addition to cleaning. Specifically, when the ultrasonic-wave irradiation unit is applied to an ultrasonic emulsification apparatus, an emulsion can be efficiently reduced to nanoscale particles, thereby enabling long-term stability and a reduction in the amount of surfactant required. When the ultrasonic-wave irradiation unit is applied to an ultrasonic dispersion apparatus, nanoparticles (such as metal nanoparticles, carbon nanotubes, ceramic nanoparticles, and magnetic nanoparticles) can be efficiently dispersed. Furthermore, the ultrasonic-wave irradiation unit may be implemented as an ultrasonic processing apparatus that utilizes chemical effects. In this case, cavitation can be generated uniformly and over a wide area with high efficiency, making it possible to increase the amount of radicals such as OH radicals that are generated in high-temperature, high-pressure fields created by bubble collapse. Accordingly, the reaction efficiency of sonochemical processes involving radical species can be improved, enabling efficient treatment such as decomposition and detoxification of hazardous substances, sterilization, and polymerization.

### DESCRIPTION OF REFERENCE NUMERALS

12: Diaphragm

12a: Long side of diaphragm

12b: Short side of diaphragm

13: Irradiation surface

14: Non-irradiation surface

21, 21A, 21B: Ultrasonic-wave irradiation unit

31: Ultrasonic transducer

32: Transducer front plate

42: Piezoelectric element

51: First resonant rod

59: Second resonant rod

D0: Maximum diameter of front plate of transducer

D1: Diameter of first resonant rod

D2: Diameter of second resonant rod

H1: Regular hexagon

L0: Center-to-center distance between adjacent ultrasonic transducers

L1: Center-to-center distance between first resonant rod and adjacent ultrasonic transducer

L2: Center-to-center distance between second resonant rod and adjacent ultrasonic transducer

p1: Center of regular hexagon

p2: Vertex of regular hexagon

1. An ultrasonic-wave irradiation unit comprising:
a diaphragm having an irradiation surface for irradiating ultrasonic waves and a non-irradiation surface located on an opposite side of the irradiation surface, the diaphragm being rectangular in plan view and having bolts projecting from the non-irradiation surface;
a plurality of bolt-clamped Langevin-type ultrasonic transducers, each including a front plate joined to the non-irradiation surface of the diaphragm; and
a plurality of resonant rods that resonate at the same frequency and in the same longitudinal oscillation mode as the ultrasonic transducers,
wherein the plurality of ultrasonic transducers and the plurality of resonant rods are fastened and fixed to the diaphragm via the plurality of bolts,
wherein the plurality of ultrasonic transducers each include four or more piezoelectric elements made of lead-free piezoelectric ceramics and are arranged at respective vertices of at least one regular hexagon assumed at a central portion of the diaphragm,
wherein the plurality of resonant rods include first resonant rods having a relatively large cross-sectional area and second resonant rods having a relatively small cross-sectional area,
wherein the first resonant rods are disposed at a center of the regular hexagon and at positions located on the short-side portion of the diaphragm and externally adjacent to the regular hexagon, and
wherein the second resonant rods are disposed on the long-side portion of the diaphragm and externally adjacent to the regular hexagon.

2. The ultrasonic-wave irradiation unit according to claim 1, wherein two regular hexagons that share one side with each other are assumed at a central portion of the diaphragm, and the plurality of ultrasonic transducers are disposed at the vertices of the two regular hexagons.

3. The ultrasonic-wave irradiation unit according to claim 1, wherein the number of the ultrasonic transducers is smaller than a total number of the first resonant rods and the second resonant rods, and wherein the number of the first resonant rods is greater than the number of the second resonant rods.

4. The ultrasonic-wave irradiation unit according to claim 1, wherein the first resonant rods are arranged linearly along a short side of the diaphragm, with at least three of the first resonant rods being arranged.

5. The ultrasonic-wave irradiation unit according to claim 1, wherein the first resonant rod has a diameter equal to the maximum diameter of the front plate of the ultrasonic transducer, and the second resonant rod has a diameter that is not less than one-half and not greater than three-fourths of the maximum diameter of the front plate of the ultrasonic transducer.

6. The ultrasonic-wave irradiation unit according to claim 1, wherein a center-to-center distance between the first resonant rod and an adjacent ultrasonic transducer is equal to the center-to-center distance between two adjacent ultrasonic transducers, and wherein a center-to-center distance between the second resonant rod and an adjacent ultrasonic transducer is shorter than the center-to-center distance between the two adjacent ultrasonic transducers.
